(19) United States
(12) Patent Application Publication
(10) Pub. No.: US 2017/0372958 A1
(43) Pub. Date: Dec. 28, 2017

(54) FILM-EDGE TOP ELECTRODE

(71) Applicant: Hewlett Packard Enterprise Development LP, Houston, TX (US)

(72) Inventor: Hans Cho, Palo Alto, CA (US)

(21) Appl. No.: 15/539,860

(22) PCT Filed: Jan. 23, 2015
(86) PCT No.: PCT/US2015/012715

§ 371 Date: Jun. 26, 2017

(51) Int. Cl. H01L 21/768; H01L 27/10; H01L 45/00

(52) U.S. Cl. CPC H01L 21/76897; H01L 45/1666; H01L 45/1253; H01L 21/76838; H01L 27/10; H01L 45/146

(57) ABSTRACT

In one example, an electronic device includes a layer of insulator on a substrate extending to a set of device elements. A first set of metal layers having a first thickness lithographically patterned and defined horizontally to the substrate on the layer of insulator. A second set of metal layers with a second thickness having a first portion defined horizontally to the substrate and patterned over and contacting the first set of metal layers, and a second portion defined vertically to the substrate and contacting the first portion and extending vertically through the layer of insulator to at least one device element and contacting the at least one device element with a width of the second thickness thereby creating at least one sub-lithographic film-edge top electrode.

### CROSS REFERENCE TO RELATED APPLICATIONS

This application is related to commonly assigned U.S. application Ser. No. 13/881,452, filed Nov. 25, 2013, which is the US national stage entry of PCT Application Number PCT/US2010/054610, “MEMRISTIVE DEVICES AND MEMRISTORS WITH RIBBON-LIKE JUNCTIONS AND METHODS FOR FABRICATING THE SAME” filed Oct. 29, 2010, which are incorporated by reference herein.

### BACKGROUND

In the last 40 years, semiconductor devices have been mainly driven by process of intensive field effect transistor (FET) transistor gate down-scaling with new lithography techniques and equipment. However, as FET gates approach sizes less than 100 nm, short channel effect problems can degrade device performance and off channel leakage can become a significant portion of the operating current and device power consumption. It is generally believed that transistor-based memories (such as those commonly known as DRAM, SRAM, Flash, etc.) may approach an end to scaling within a decade.

Other non-volatile random access memory devices have been explored as next generation high density memory devices. These devices often require new materials and device structures in order to couple with silicon-based devices to form a functional memory cell, and usually lack one or more key attributes. Desirable attributes of a high density device include high switching speed, reliable switching, high endurance, and CMOS compatibility, among others. Further, memory cell performance can be affected by temperature and therefore, thermal confinement is also desired in order to improve reliability

### BRIEF DESCRIPTION OF THE DRAWINGS

The disclosure is better understood with reference to the following drawings. The elements of the drawings are not necessarily to scale relative to each other. Rather, emphasis has instead been placed upon clearly illustrating the disclosure. Furthermore, like reference numerals designate corresponding similar parts through the several views.

FIG. 1 is a top view illustration of a crossbar memory in an example;

FIG. 2 is an illustration of an electronic device having a top electrode in an example;

FIG. 3A is a cross-sectional drawing through one electronic device in a cross-bar array in an example of a structure;

FIG. 3B is top view of the example electronic device shown in FIG. 3A;

FIG. 4 is a simplified 3D view of the example electronic device shown in FIGS. 3A and 3B;

FIG. 5 is an example of a starting substrate similar to the example in FIG. 3A;

FIG. 6 is another example of a starting substrate;

FIG. 7 is another example of a starting substrate;

FIGS. 8A-8F are example process steps to create the example substrate shown in FIG. 5; and

FIGS. 9A-9F are example process steps to create an example top electrode as shown in FIGS. 1-4.

### DETAILED DESCRIPTION

The present disclosure is related to electronic devices, such as memory devices, switching devices, sensors and other electronic devices which may benefit from a film-edge top electrode which improves memory cell performance. More principally to clarify the claimed subject matter, the present disclosure describes a storage memory device characterized by a top electrode that is formed of an edge of a thin film and used to reduce the effective active area of the electronic device. Examples of the present disclosure have been applied to fabrication and operation of a resistive random access memory device. However, it should be recognized that the disclosed subject matter can have a much broader range of applicability to other types of electronic devices such as other memories, switches, sensors, and emitters, just to name a few examples.

Many memory cell structures have multiple layers of material, often known as “stacks”. These stacks may include one or more memory element, a switching element or other selector, sensors, and various combinations depending on desired device performance. Further, the nanoscale top electrode may be useful with stacks of other device types such as for Boolean logic implementations, and neuro-morphic systems. The stacks used to create devices may include perovskite oxides, binary transition metal oxides, wide band-gap high-k dielectric oxides, higher chalcogenides, and carbon-based materials.

Many stacks may be organized as one or more layers of cross-bar arrays of intersecting wires or conductors, typically of nanoscale dimensions. Although the nanowire conductors of crossbar arrays used as examples are shown with rectangular cross sections, nanowires can also have square, trapezoidal, circular, elliptical, or more complex cross-sectional geometries. The nanowires may also have many different widths, diameters, aspect ratios, or eccentricities. The term “crossbar” may refer to crossbars having at least two layers of nanowires, sub-microscale wires, microscale wires, or wires with larger dimensions.

For instance, a memristor resistive memory cell structure, may include stacks with both a resistive switching element and a non-linear selector element. However, to meet an overall device performance requirement, the various elements of the stack may have competing requirements. For instance, if leakage current reduction is needed in the overall device, this feature requires a higher resistance for the memory device and/or selector. Conversely, today's semiconductor devices (particularly CMOS) operate with very low voltages and these voltages are typically the only ones available in a system to be used for electroforming, programming (switching, writing, or erasing), and reading the memory devices. Having only these very low voltages available requires that the memory devices have a lower resistance due to the necessary power required to change memory states. Even with a given set of materials for the stack and a given lithography required cell dimension, the resistance value at which the tradeoff of these two requirements is optimized may still not meet the desired overall device performance requirements.

Simply reducing the size of the device lithographically does not resolve the conflicting requirements. As noted, shrinking the lithography eventually may have the effect of increasing the leakage current. While an increased resistance presumably may reduce leakage, it increases the electroforming and read/write voltages of a memory cell. Indeed, after electroforming a memory cell at a high voltage to enable it to operate as a memory cell, the cell itself may become extremely leaky.

The present disclosure describes a) a process to create nano-scale metal electrodes; b) an electronic device with the nano-scale metal electrode; and c) use of the electronic device in a crossbar memory that is fabricated with typical lithographic row and column line design rules. It is the inventor's insight that by decreasing the contact and cross-sectional area of a metal electrode contacting the device, thermal confinement can be increased while at the same time reducing the voltages needed to program the memory. By not changing the typical lithographic design rules but only a few process steps, the performance of the memory system need not suffer due to increased resistance and long RC (resistor-capacitance) delay times. In fact, while the nano-scale electrodes are extremely small and concentrate the applied electric field onto a smaller area of the electronic device, their series resistance affects only the cell they contact, and does not contribute to the overall line resistance.

For a memory cell, this enhances the power efficiency of programming. For example, an equivalent writing, erasing, or electroforming event can be achieved with a smaller voltage than that used with currently larger lithography defined electronic devices and/or achieved in a faster time. Accordingly, the performance of the memory system increases due to the lower power consumption and faster programming and reading of the memory devices using the nano-scale electrode.

Further, the nano-scale electrodes, and the resulting narrow effective resistive memory cell area, provide an inherent series resistance in the memory cell but not in the memory array row and column wiring and thus limits leakage and switching currents. This effect is achieved without narrowing the row and column line wires ensuring that their resistance is not significantly increased which would slow down the overall operation of the memory due to RC delay.

In fact, the actual effective switching areas and volumes of the switching regions in the resistive memory are significantly smaller than the overall switching material structure defined by the lithographic patterning for the memory cell stack. As a result, only a portion of the stack of switching materials are subjected to high currents and temperatures. The remaining surrounding stack of switching material also helps to function as a reservoir of oxygen or oxygen vacancies in the lateral direction, thereby increasing the endurance and lifetime of performance.

An additional benefit of the nanoelectrode structure is that the thickness of a nanoelectrode deposited by a means with a well-calibrated deposition rate, such as ALD, is much more precisely controllable and repeatable than the lithographically defined dimension of a patterned electrode line or via. Therefore the uniformity of dimension among and between different devices is enhanced.

There are many mechanisms by which programmable resistive device may operate and take advantage of the claimed subject matter, including polarity changes in ferroelectric oxides, charge trapping and releasing of the defects in a depletion layer, resonant tunneling through a barrier, the presence of low dielectric layer and interface states, and field induced drift of dopants. For instance, with field induced drift of oxygen vacancy dopants, under the influence of an electric field the oxygen vacancies are drawn into an interface region in the stack, reducing the electronic barrier and thus resulting in a lower resistance state. When an opposite polarity electric field is applied, the oxygen vacancies are repelled away from the interface region in the stack resulting in a higher resistance state. By having nano-scale top electrode structures, the electric field required for oxygen vacancy movement can be created with lower voltages and the smaller area allows for less current as there are fewer oxygen vacancies to be moved.

The semiconductor devices of the present disclosure are applicable to a broad range of semiconductor device technologies and can be fabricated from a variety of semiconductor materials. The following description discusses several presently preferred examples as implemented on silicon substrates, since the majority of currently available semiconductor devices are fabricated on silicon substrates and the most commonly encountered applications of the present disclosure will involve silicon substrates. Nevertheless, the claimed subject matter may also advantageously be employed on silicon-on-sapphire, gallium arsenide, germanium, and other semiconductor materials. Accordingly, the claimed subject matter is not intended to be limited to those devices fabricated in silicon semiconductor materials, but will include those devices fabricated in one or more of the available semiconductor materials and technologies available to those skilled in the art, such as thin-film-transistor (TFT) technology using polysilicon or other conductors on glass substrates, as well as on plastic, paper, ceramic, or metallic substrates.

It should be noted that the drawings in this disclosure are not true to scale. Further, various parts of the active elements have not been drawn to scale. Certain dimensions have been exaggerated in relation to other dimensions in order to provide clearer illustration and understanding.

In addition, although some of the examples illustrated herein are shown in two-dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device.

Moreover, while the drawings illustrated are directed to particular electronic devices, it is not intended that these illustrations be a limitation on the scope or applicability of the claimed subject matter. It is not intended that the electronic devices shown be limited to the physical structures illustrated. These structures are included to demonstrate the utility and application of the claimed subject matter to particular examples.

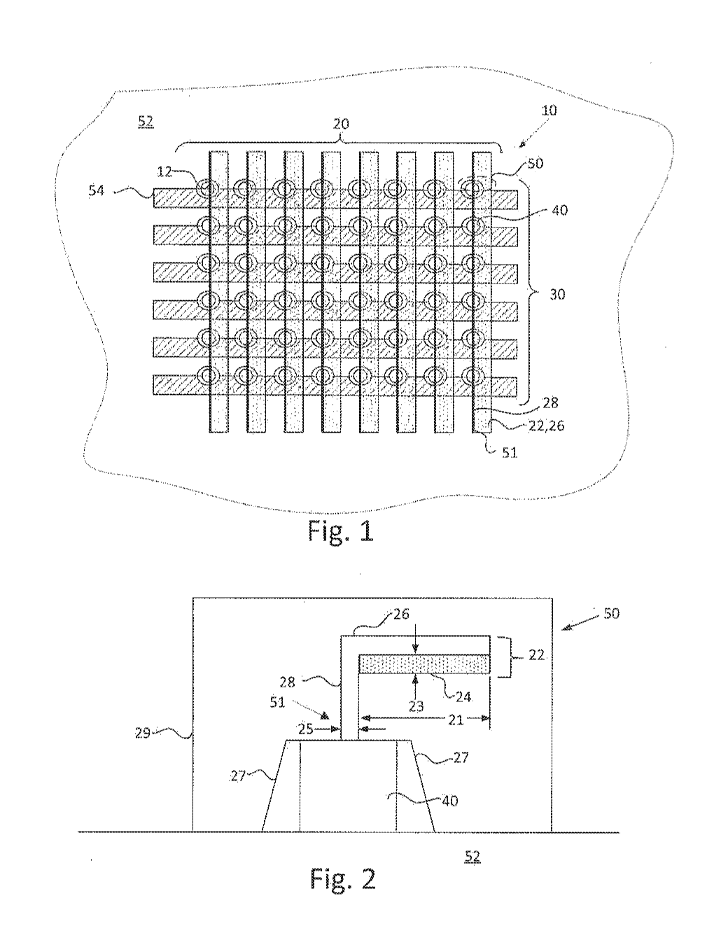

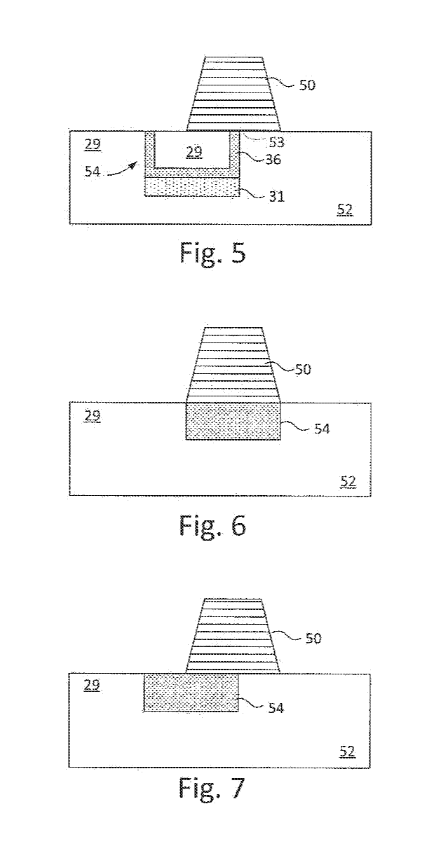

FIG. 1 is a top view illustration of a crossbar array 10 in one example that includes at least one electronic device 50. The cross-bar memory 10 has a set of parallel row lines 30 and a set of parallel column lines 20 disposed at an angle to the row lines 30. While the example shown illustrates the angle as 90 degrees, the angle in some implementations may be 45 degrees, 60 degrees, 30 degrees, or any value as needed to provide the overlap of the column lines 20 and row lines 30. Row lines 30 and column lines 20 are made up of a set of conductive layers (for example, see row line 54 in FIGS. 5-7, and column line 22 in FIG. 2) that include one or more of the set of metal layers, semiconductor layers, doped semiconductor layers, carbon nano-films, conductive polymer, or other conductive material. Also shown in FIG. 1 on column lines 20, is a sub-lithographic film-edge electrode 51 having a first portion 26 disposed on and contacting top of the column lines 20, and a second portion 28 that is defined vertically to a substrate 52 (see FIG. 2) and to the first portion 26. The second portion 28 extends vertically to a device element 40.

The column lines 20 and row lines 30 may include layers of metal conductive including as just a few examples, but not limited to, copper (“Cu”), aluminum (“Al”), tungsten (“W”), gold (“Au”), or platinum (“Pt”); titanium nitride (“TiN”). The electronic devices 50 may be embedded within an insulating material, which can be silicon dioxide (SiO₂), aluminum oxide (“Al₂O₃”) or another suitable interlayer dielectric (ILD).

FIG. 2 is an illustration of an electronic device having a top electrode in an example in cross-section of electronic device 50 to show the contact of a film-edge electrode 51 to device element 40. The electronic device 50 is enclosed within an insulating layer 29 of material, such as an ILD. The electronic device 50 is disposed on a substrate 52 that may include a silicon substrate with CMOS devices to control the cross-bar array 10. Also, there may be one or more additional cross-bar arrays 10 below or above the device element 40, particularly when a storage system is created using multiple layers of cross bar arrays in a 3D stacked configuration.

The device element 40 is shown in this example as being encladded in a sidewall cladding 27 which may be used to help in thermal isolation and to prevent migration of charge carriers used in the construction and operation of device element 40. For example, the set of device elements 40 may be approximately cylindrically etched and have at least one sidewall cladding layer 27, such as an insulator, resistive switching material, negative differential resistance material, semiconductor, or metallic material. The device element 40 is contacted on its top by the second portion 28 which has a thickness 25. The thickness 25 may be accurately controlled depending on the deposition process, such as with atomic layer deposition (ALD) which allows for very fine resolution, such as 1 or 2 nm in thickness. Contrarily, the width 21 of the column line 22 is defined by a lithographic process and varies depending on the masking, etching, and lithography technique used. Its width is generally greater than 10 nm and typically is on the order of greater than 20 nm to allow for low column resistance in a large storage device. To help lower the column resistance and prevent metal migration, the column line 22 may be made of one or more layers, such as first column layer 24 of conductive material having a thickness 23 as needed to achieve the desired low resistance, including tungsten (W), copper (Cu), titanium nitride (TiN), tantalum nitride (TaN), aluminum, and others. However, while the first column layer 24 materials may be chosen for low resistance and other factors, those conductive materials may not be the proper material for contacting device element 40 as there may be Schottky effects, electro-migration, contamination issues, etc. Therefore, a second column layer of first portion 26 may be deposited or otherwise applied to the top of first column layer 24. This first portion 26 will be deposited along with second portion 28 and thus its thickness 25 may be too narrow to meet the desired column lines resistance for the entire crossbar array 10. Accordingly, having column line 22 have multiple layers of conductive material of varying thickness, allows for the separate design choices of width and depth to set the resistance of the column lines and thickness 25 of the film-edge electrode 51.

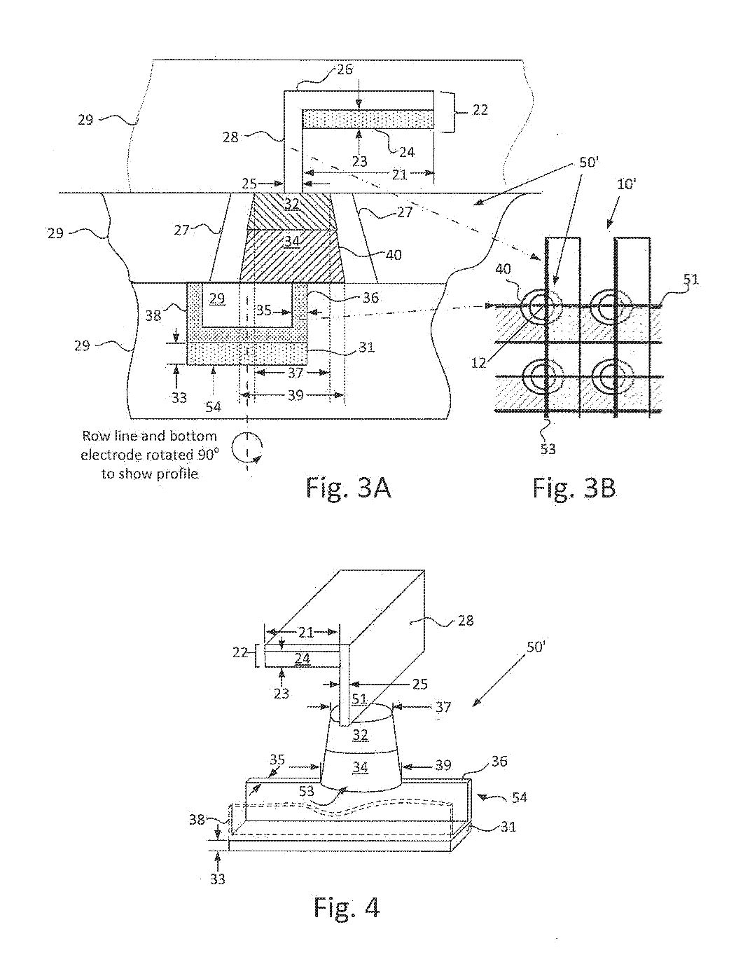

FIG. 3A is a cross-sectional drawing through another example electronic device 50′ in a cross-bar array 10′. In this example, the electronic device 50′ has in addition to the film-edge electrode on the top of device element 40, a film-edge electrode 53 contacting the bottom of device element 40. In this example, electronic device 50′ is enclosed in three layers of insulator 29. FIG. 3B is top view of the example electronic device 50′ shown in FIG. 3A. For ease of illustration, the row line 54 and bottom film-edge electrode 53 have been rotated 90 degrees to show their profile.

FIG. 4 is a simplified 3D view of the example electronic device shown in FIGS. 3A and 3B to better illustrate the structure of electronic device 50′ without the insulators 29, side cladding 27, or portions of row line 54 which would obscure the view. The top film-edge 51 is as described in FIG. 2 previously. The device element 40 is shown in this example as having a combination of devices, such as a selector element 32 and a memory element 34. Selector element 32 may be a diode or other non-linear device used to prevent current leakage to other devices such as when programming or reading memory element 34. In some examples, the selector element 32 and memory element 34 may be integrated and their functions provided by anionic or other charged carriers manipulated by voltages, electric fields, pressure, temperature, or magnetic fields.

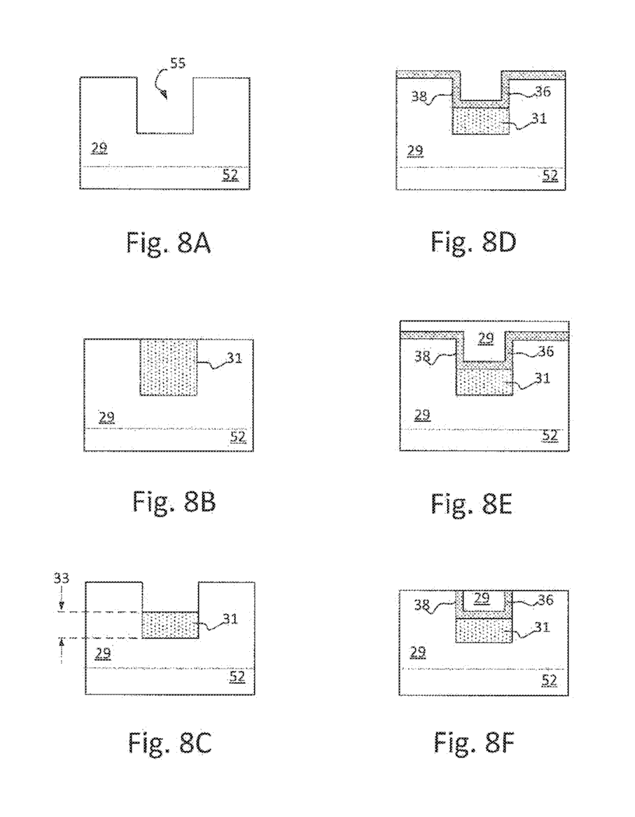

In FIG. 3A, the bottom row line 54 may be made of one or more layers of conducting material as described previously for the column line 22. A first row layer 31 may be deposited or otherwise applied within an insulator 29 to a thickness 33 as necessary to achieve a desired resistance for the crossbar array 10′. A second conductive layer having one or two vertical film-edge electrode portions 36, 38 is deposited or otherwise applied on the first row layer 31. As shown in FIG. 3A and FIG. 4, one film-edge electrode 36 contacts and extends from the first row layer 31 to the bottom of device element 40 to create bottom film-edge electrode 53. In this example, an insulator 29 is disposed between the two vertical film-edge electrodes 36 and 38. The two vertical film-edge electrode portions 36, 38 and thus bottom film-edge electrode 53 have a thickness 35, while the first row layer 31 has a separate thickness 33 which may be substantially greater than thickness 35. An example process to construct the bottom film edge electrode is shown and described in FIGS. 8A-8F.

As shown in FIG. 3B and FIG. 4, the top film-edge electrode 51 and the bottom film edge electrode 53 intersect with device element 40 creating an effective total area 52 of the device element 40 of the thickness 25 of the top film-edge electrode 51 times the thickness 35 of the bottom film-edge electrode 53. This effective total area 52 is substantially less than the total effective area of the intersection of the row line and the column line without the film edge electrodes or an area defined by the top diameter 37 and bottom diameter 39 of the device element 40. For example if the film thickness of both the top and bottom film-edge electrodes were deposited at 2 nm of thickness, the total effective area would be 4 nm². Even if a state of the art 14 nm lithographic process were used for the row and column lines, a typical effective area would be 196 nm² or substantially about 50 times larger.

FIG. 5 is one example of a starting substrate similar to the example in FIG. 3A showing the bottom row line 54 having a first conductive layer 31 and a second conductive layer 36 with two portions extending from the first conductive layer 31 to the top surface of the substrate 52. On the surface of the substrate 52 is an electronic device 50 which may a storage device, a sensor device, such as for sensing light, or other. One portion of second conductive layer 36 forms the bottom film edge electrode 53 that contacts the bottom of electronic device 50.

FIG. 6 is another example of a starting substrate 52. In this example, the row line 54 is a conventional row line that contacts electronic device 50 without a bottom film edge electrode. For instance, if the electronic device 50 were a photonic sensor, the row line 54 could act as a photon blocker for any photon that might transit through the insulator 29. This example shows, assuming a 14 nm lithographic state of the art process, that even if only the top film-edge electrode is used, the total effective area would be 2 nm×14 nm or 28 nm², which is still significantly 7 times smaller than the typical 196 nm².

FIG. 7 is another example of a starting substrate 52. In this example, the electronic device 50 is placed over a portion of the edge of row line 54 which does not have a film-edge electrode. In this example, the area of the row line 54 contact with electronic device 50 is reduced while the electric field is still enhanced somewhat due to the corner edge. This approach might be used where increased performance due to an increased electric field is desired, but due to internal heating of the electronic device 50, the row line 54 could be used to help couple the heat away. For instance, some memory device technologies use joule heating to form memory states. Further, this example shows, assuming a 14 nm lithographic state of the art process, that even if only the top film-edge electrode is used and the row line shifted 50%, the total effective area would be 2 nm×7 nm or 14 nm², which is still 14 times smaller than the typical 196 nm². Accordingly, the top film-edge electrode provides a substantial improvement is reducing the effective device area independent of the bottom device electrode but most improvement is with a bottom film-edge electrode.

FIGS. 8A-8F are example process steps to create the example substrate with the bottom film edge electrode shown in FIG. 5. In FIG. 8A, a substrate 52 is first created with an insulating layer 29 that is masked and etched to create a row channel 55. The row channel 55 may be formed using chemical wet etching, reactive-ion etching (“RIE”), focused ion beam milling (“FIB”), or any other suitable technique for forming grooves in an insulating material. This row channel 55 is then filled with first row layer conductor 31 in FIG. 8B. This first row layer conductor 31 is then etched to create the desired thickness 33 in FIG. 8C. This recess etching to form a row conductor embedded in the insulator 29 can use chemical wet etching or dry etching such as RIE.

Then in FIG. 8D, a second row layer conductor is deposited over the insulator 29 and first row layer conductor 31 to create the two vertical portions, 36, 38. This second row layer conductor may be a thin layer 1208 of TiN, Pt, TaN, or W conformally deposited using chemical vapor deposition (“CVD”), physical vapor deposition (“PVD”), or atomic layer deposition (ALD).

In FIG. 8E an additional insulator 29 is deposited over the second row layer conductor and planarized such that the area in the row channel 55 between the two vertical portions 36, 38 is filled with insulator 29. Planarization can be performed using chemical mechanical polishing (“CMP”). Further planarization is performed in FIG. 8F to remove the upper horizontal portions of the second row conductor, leaving the two vertical portions 36, 38 of which one or more can be used as a bottom film-edge electrode 35.

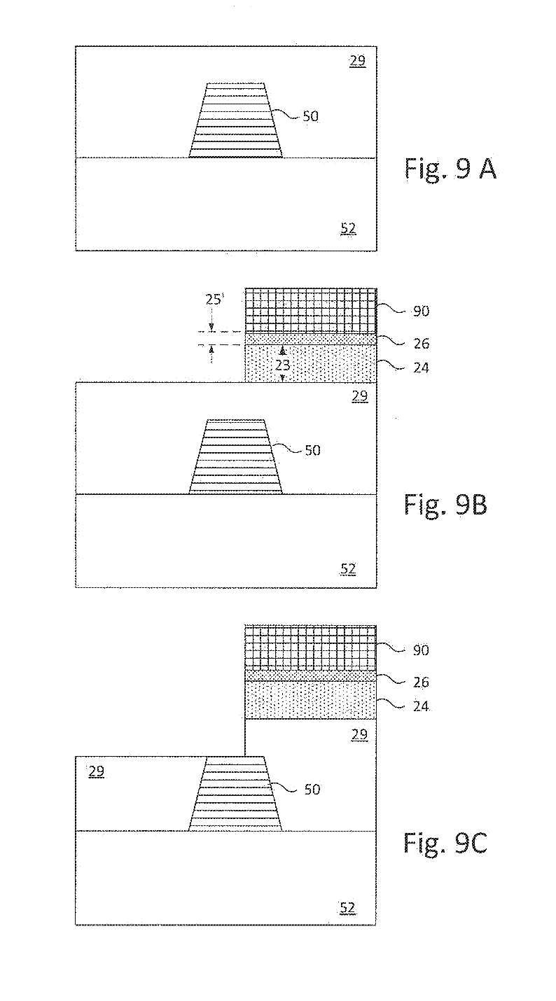

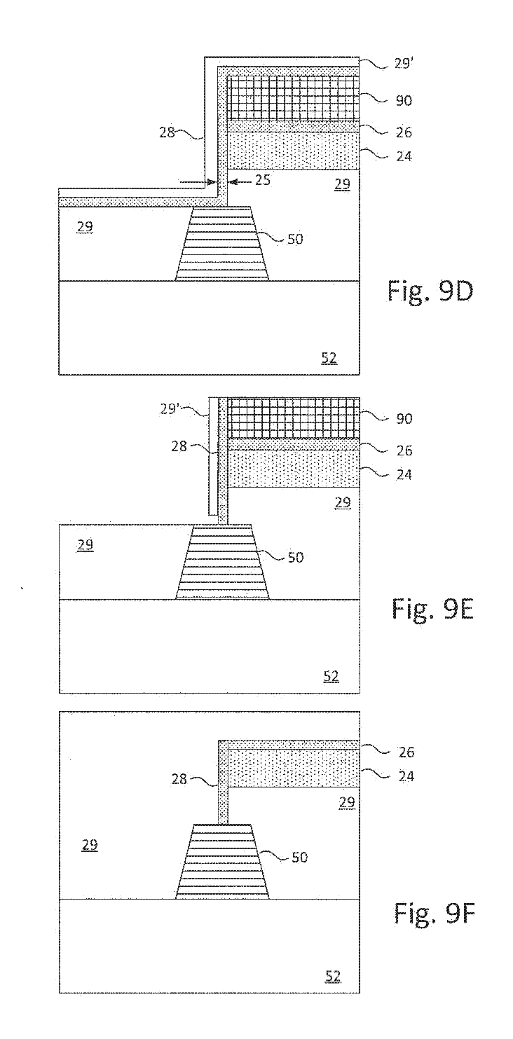

FIGS. 9A-9F are example process steps to create an example top electrode as described in FIGS. 1-4. In FIG. 9A a starting substrate (such as any of FIGS. 5-7, but others are possible) is provided. One or more electronic device 50 are created by depositing one or more layers of material on the substrate. The electronic device 50 is covered with an insulator 29 and planarized to create a flat surface on the insulator 29 and a thickness of insulator over the electronic device 50.

FIG. 9B shows that one or more layers of column conductors, such as first column conductor 24 to a thickness 23 and second column conductor 26 to a thickness 25′. A mask layer 90 is then deposited on the column conductors where the column lines are to be created. The remaining column conductors' material is then etched or otherwise removed from where there is no mask layer 90 material. In this example, the column conductors' edges after etching are about in the center of the electronic device 50 but separated by the thickness of insulator 29. A further etching step in FIG. 9C is then performed to remove the insulator 29 that is not covered over by the mask layer 90 to expose a portion of the top surface of electronic device 50.

In FIG. 9D, a third row conductor is conformally deposited to a thickness 25 (which may be the same, more, or less than 25′, but typically the same) for the second portion 28 which contacts the top of the mask layer, the first portion 26 and the first column conductor 24 on the exposed edges. The second portion 28 also extends down to the top of the electronic device 50 and the surface of insulator 29. A thin layer of insulator 29′ is then formed by conformally depositing it on the third column conductor layer. A vertical etch is then preformed in FIG. 9E to remove the horizontal portions of thin layer of insulator 29′ and the horizontal portions of third column conductor leaving the second portion 28 extending to the top surface of electronic device 50 thereby creating the top film-edge electrode 51. In FIG. 9F, further vertical etching or lift-off is used to remove the mask layer 90 and the adjacent portions of thin layer of insulator 29′ and second portion 28 that extend above the first portion 26. Finally, an additional deposition of insulator 29 is conformally deposited over the substrate and planarized.

Accordingly, an electronic device has at least one sub-lithographic film-edge top electrode and includes a layer of insulator on a substrate extending to a set of device elements. A first set of metal layers having a first thickness is lithographically patterned and defined horizontally to the substrate on the layer of insulator. A second set of metal layers having a second thickness includes a first portion defined horizontally to the substrate and patterned over and contacting the first set of metal layers. A second portion defined vertically to the substrate and contacts the first portion and extends vertically through the layer of insulator to at least one device element. The at least one device element is contacted with a width of the second thickness thereby creating the at least one sub-lithographic film-edge top electrode.

One example process for creating a film-edge top electrode includes depositing and patterning a first set of metal layers to a first thickness and a hard mask layer on a substrate having a planar insulating surface, the substrate contains a set of device elements. The insulating surface is etched to expose at least one of the device elements. A second set of metal layers having a second thickness and an insulating film are conformally deposited over the substrate. The second set of metal layers contacts the first set of metal layers and the at least one device element. A portion of the conformal deposited layers is etched to remove horizontal portions of the second set of metal layers and insulating film while leaving vertical portions of the second set of metal layers and the insulator film extending from the first set of metal layers to contact with the at least one device element with a width of the second thickness. This contact creates the at least one sub-lithographic film-edge top electrode. The hard mask layer is removed and the surface of the substrate is conformally filled with an inter-layer dielectric (ILD) and planarized.

A crossbar array includes a set of device elements at cross-points on a substrate. The crossbar array also includes a set of row lines deposited to the substrate and extending in a first direction. The row lines have at least one film-edge with a first thickness extending vertically from the row line through an insulator covering the bulk of the row line. A set of column lines are deposited to the substrate and extend in a second direction. The column line has at least one film-edge with a second thickness extending vertically from the column line through an insulator under the bulk of the column line. A set of device elements are disposed at the cross-point intersections of the set of row lines and set of column lines between the at least one film-edge of the row line and the at least one film edge of the column line. The effective total area of the at least one device element is the first thickness times the second thickness. The set of device elements have a total lithography defined area greater than the effective total area. The set of device elements may include a selector and memory element, including resistive memory elements with mobile carriers. These elements may be cylindrically etched and have a sidewall cladding for thermal isolation and to prevent loss of the mobile carriers into the surrounding material.

This description and claimed subject matter should be understood to include all novel and non-obvious combinations of elements described herein and their equivalents. Further, additional claims may be presented in this or a later application to any novel and non-obvious combination of these elements. The foregoing examples are illustrative, and no single feature or element is essential to all possible combinations that may be claimed in this or a later application. Where the claims recite “a” or “a first” element of the equivalent thereof, such claims should be understood to include incorporation of one or more such elements, neither requiring nor excluding two or more such elements.

What is claimed is:

1. An electronic device having at least one sub-lithographic film-edge top electrode, comprising:
a layer of insulator on a substrate extending to a set of device elements;
a first set of metal layers having a first thickness lithographically patterned and defined horizontally to the substrate on the layer of insulator; and
a second set of metal layers having a second thickness having,
a first portion defined horizontally to the substrate and patterned over and contacting the first set of metal layers, and
a second portion defined vertically to the substrate and contacting the first portion and extending vertically through the layer of insulator to at least one device element and contacting the at least one device element with a width of the second thickness thereby creating the at least one sub-lithographic film-edge top electrode.

2. The electronic device of claim 1, further comprising:
a sub-lithographic film-edge bottom electrode having a third thickness contacting the at least one device element wherein the effective total area of the at least one device element is the second thickness times the third thickness.

3. The electronic device of claim 1 wherein the set of device elements include at least one memory element.

4. The electronic device of claim 3 wherein the memory element is a resistive random access memory.

5. The electronic device of claim 1 wherein the set of device elements are formed into a crossbar array.

6. A process for creating a film-edge top electrode, comprising:
depositing and patterning a first set of metal layers to a first thickness and a hard mask layer on a substrate having a planar insulating surface, the substrate containing a set of device elements;
etching the insulating surface to expose at least one of the device elements;
conformally depositing a second set of metal layers having a second thickness and an insulating film over the substrate, the second set of metal layers contacting the first set of metal layers and at least one device element; and
etching a portion of the conformal deposited layers to remove horizontal portions of the second set of metal layers and insulating film and leaving vertical portions of the second set of metal layers and the insulator film extending from the first set of metal layers to contact with at least one device element with a width of the second thickness thereby creating the at least one sub-lithographic film-edge top electrode.

7. The process of claim 6, further comprising:
removing the hard mask layer;
filling the surface of the substrate with an inter-layer dielectric (ILD); and
planarizing the ILD.

8. The process of claim 6, further comprising:
creating a bottom film-edge electrode having a third thickness on the substrate contacting the at least one device element.

9. The process of claim 8, wherein creating a bottom film-edge electrode on the substrate further comprises:
depositing a third set of metal layers patterned and defined on the substrate, and
depositing a fourth set of metal layers with the third thickness having,
a first portion defined horizontally to the substrate and contacting the third set of metal layers, and
at least one second portion contacting the third set of metal layers and extending vertically from the substrate terminating in an edge with the third thickness thereby creating the bottom film-edge electrode.

10. The process of claim 8 further comprising the step of depositing the set of device elements on the substrate wherein at least one device element contacts the bottom film-edge electrode.

11. A crossbar array, comprising:
a set of row lines deposited horizontally to the substrate, the row lines having at least one film-edge having a first thickness extending vertically from the row line through an insulator covering the bulk of the row line;
a set of column lines deposited horizontally to the substrate, the column line having at least one film-edge having a second thickness extending vertically from the column line through an insulator under the bulk of the column line; and
a set of device elements disposed at the intersections of the set of row lines and set of column lines between the at least one film-edge of the row line and the at least one edge of the column line wherein the effective total area of at least one device element is the first thickness times the second thickness.

12. The crossbar array of claim 11 wherein the set of device elements have a total lithography defined area greater than the effective total area.

13. The crossbar array of claim 12 wherein the set of device elements include a selector and memory element.

14. The crossbar array of claim 12 wherein the set of device elements are approximately cylindrically etched and have at least one sidewall cladding layer, consisting of an insulator, resistive switching material, negative differential resistance material, semiconductor, or metallic material.

15. The crossbar array of claim 12 wherein the set of device elements are resistive memory device elements.
